(19) United States
(12) Patent Application Publication
(10) Pub. No.: US 2008/0035969 A1
(43) Pub. Date: Feb. 14, 2008

(54) CMOS image sensors and methods of forming the same

(75) Inventors: Ju-Hyun Ko, Seongnam-si (KR); Yong-Jei Lee, Seongnam-si (KR); Jung-Chak Ahn, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/889,501

(22) Filed: Aug. 14, 2007

(30) Foreign Application Priority Data
Aug. 14, 2006 (KR) 10-2006-0076868

(51) Int. Cl. H01L 31/062; H01L 21/02

(52) U.S. Cl. 257/292; 438/59; 257/E31.073

(57) ABSTRACT

Example embodiments may provide a CMOS image sensor and example methods of forming the same. Example embodiment CMOS image sensors may include a transfer gate insulating pattern between a transfer gate and an active region. A photodiode region and/or a floating doped region may be in the active region at either side of the transfer gate. The transfer gate insulating pattern may include a first part adjacent to the photodiode region and/or a second part adjacent to the floating doped region. The first part may be thicker than the second part.

### PRIORITY STATEMENT

This U.S. non-provisional patent application claims priority under 35 U.S.C. §119 of Korean Patent Application No. 2006-76868, filed on Aug. 14, 2006, in the Korean Intellectual Property Office, the disclosure of which is incorporated herein in its entirety by reference.

### BACKGROUND

Example embodiments may relate to semiconductor devices and methods of forming the same, for example, to complementary metal-oxide-silicon (CMOS) image sensors and methods of forming the same.

Related art image sensors in semiconductor devices may convert an optical image into an electric signal. The image sensor may be a CMOS sensor or a charge coupled device (CCD) device. The CCD image sensor may have improved sensitivity and/or noise characteristics compared to a CMOS image sensor. However, a CCD image sensor's higher degree of integration may not be easily achieved, and its power consumption may be relatively higher. CMOS image sensors may be formed using simpler processes, and a CMOS image sensor may have lower integration and/or less power consumption compared to the CCD image sensor. Sensitivity and/or noise characteristics of CMOS image sensors may be improving and use of CMOS image sensors may be increasing.

Such a related art CMOS image sensor is described in part in FIG. 1. As shown in FIG. 1, a gate oxide layer 2 and/or a gate electrode 3 may be stacked on a semiconductor substrate 1. A photodiode region 4 may be on the semiconductor substrate 1 on one side of the gate electrode 3. A floating doped region 5 may be on the semiconductor substrate 1 in the other side of the gate electrode 3. The gate oxide layer 2 may have a uniform thickness. The photodiode region 4 may be doped with dopant different from that of the semiconductor substrate 1. The semiconductor substrate 1 and the region 4 may constitute a PN junction forming a photodiode that may receive external light in the photodiode region 4.

Related art image sensors shown in FIG. 1 may have some shortcomings. For example, if external light is not incident on the image sensor, a dark current may flow from the photodiode region 4 to the floating doped region 5. The dark current may be due to several conditions. For example, if an operating voltage is applied to the gate electrode 3, dark current may be due to the electric field applied to an overlapping region of the gate oxide layer 2 and the photodiode region 4. The electric field may cause electrons to be trapped in the gate oxide layer 2 adjacent to the photodiode region 4. Dark current may occur due to the trapped electrons.

### SUMMARY

Example embodiments may provide CMOS image sensors with reduced or minimized characteristic deterioration and example methods of forming the same.

Example embodiments may provide CMOS image sensors that reduce or minimize dark current and example methods of forming the same.

Example embodiments may provide CMOS image sensors including a transfer gate on an active region defined in a substrate, a transfer gate insulating pattern between the transfer gate and the active region, and/or a photodiode region and a floating doped region on the active region on either side of the transfer gate. The transfer gate insulating pattern may include a first part and a second part positioned side by side, the first part being adjacent to the photodiode region and being thicker than the second part, the second part being adjacent to the floating doped region.

The first part may have a thickness that increases with proximity to the photodiode region. Alternatively, the first part may include a substantially uniform thickness. The first part may include a uniform region adjacent to the second part and a non-uniform region adjacent to the photodiode region, the uniform region having a substantially uniform thickness, the non-uniform region having a thickness that increases with proximity to the photodiode region. The second part may include a substantially uniform thickness. An edge of the second part adjacent to the floating doped region may overlap with an edge of the floating doped region.

Example embodiment CMOS image sensors may further include a sensing gate on the active region and electrically connected to the floating doped region, a first doped region and a second doped region having different dopants formed in the active region at either side of the sensing gate, and a sensing gate insulating pattern between the sensing gate and the active region. A supply voltage may be applied to the first doped region and the sensing gate insulating pattern may include a third part and a fourth part that may be side by side, the third part adjacent to the first doped region and being thicker than the fourth part.

Example methods of forming CMOS image sensors may include stacking a transfer gate insulating pattern and a transfer gate on an active region in a substrate, the transfer gate insulating pattern including a first part and a second part side by side, forming a photodiode region in the active region at a side of the transfer gate, and forming a floating doped region in the active region at the other side of the transfer gate, the first part being adjacent to the photodiode region and being thicker than the second part, the second part adjacent to the floating doped region.

### BRIEF DESCRIPTION OF THE FIGURES

The above and other features and/or advantages of example embodiments will become more apparent by describing in detail the attached drawings in which:

FIG. 1 is a profile view of a related art CMOS image sensor;

FIG. 2 is a an equivalent circuit diagram of an example embodiment CMOS image sensor;

FIG. 3 is a profile view of an example CMOS image sensor;

FIGS. 4 through 7 are profile views illustrating an example method of forming CMOS image sensors;

FIGS. 8 through 10 are profile views illustrating an example method of forming CMOS image sensors;

FIG. 11 is a profile view of an example embodiment CMOS image sensor;

FIGS. 12 and 13 are profile views illustrating an example method of forming a CMOS image sensor;

FIG. 14 is a profile view of an example embodiment image sensor;

FIGS. 15 and 16 are profile views illustrating an example method of forming image sensors; and

FIGS. 17 through 19 are profile views illustrating an example method of forming image sensors.

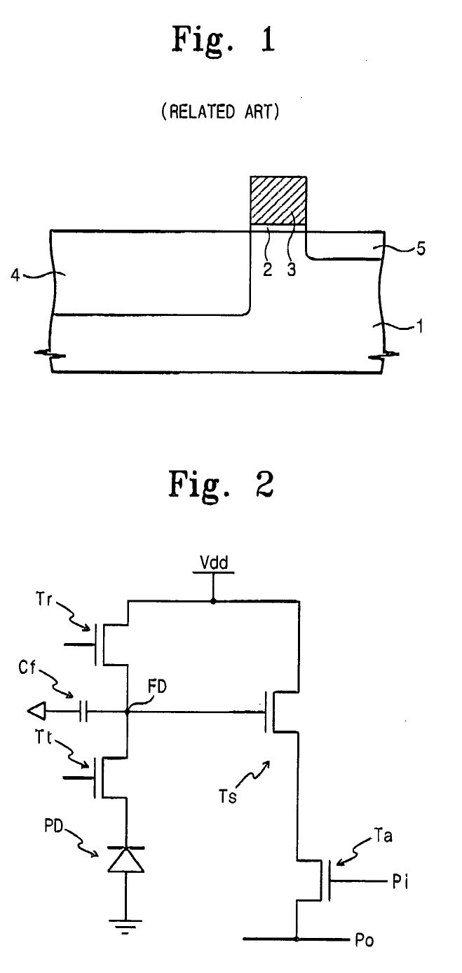

### DETAILED DESCRIPTION

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

FIG. 2 is an equivalent circuit diagram of an example embodiment CMOS image sensor.

As shown in FIG. 2, a pixel of example embodiment image sensors may include a photodiode PD. The photodiode PD may receive external light and/or convert it into an electric signal. The pixel may further include transistors Tt, Tr, Ts, and Ta that may control electric charge stored in the photodiode PD. One terminal of the photodiode PD may be connected to a source of the transfer transistor Tr. The other terminal of the photodiode PD may be grounded. A drain of the transfer transistor Tt may be connected to a floating doped region FD. The floating doped region FD may include a floating capacitor Cf.

A gate of the sensing transistor Ts may be connected to the floating doped region FD, and a supply voltage Vdd may be applied to a drain of the sensing transistor Ts. The sensing transistor Ts may be a source follower transistor. A reference mark Ts may represent the sensing transistor. A source of a reset transistor r may be connected to the floating doped region FD, and the supply voltage Vdd may be applied to a drain of the reset transistor Ts. A source of the sensing transistor Ts may be connected to a drain of the access transistor Ta. A source of the access transistor may be connected to an output port Po, and a gate of the access transistor Ta may be connected to an input port Pi. If a turn-on voltage is applied through the input port Pi, the access transistor Ta may be turned on and electric data with image information may be output through the output port Po. A turn-on voltage, which may be applied to the input port Pi, the gate of the transfer transistor, and the gate of the reset transistor Tr, may be identical or close to the supply voltage Vdd.

The transistors constituting a pixel in the equivalent circuit may be NMOS transistors as described below. In a case of NMOS transistors, the supply voltage Vdd may be a positive supply voltage. In a case of PMOS transistors, the supply voltage Vdd may be a negative supply voltage.

According to an example method of operating the pixel, electric charge may accumulate in the photodiode PD if external light is incident to the photodiode PD. This may turn on the transfer transistor Tt to transfer electric charges from the photodiode PD to the floating doped region FD. An electric potential of the floating doped region FD may change and the electric potential of the gate of the sensing transistor Ts may change. Due to the intensity of the external light, an electric signal may be output from the pixel changes.

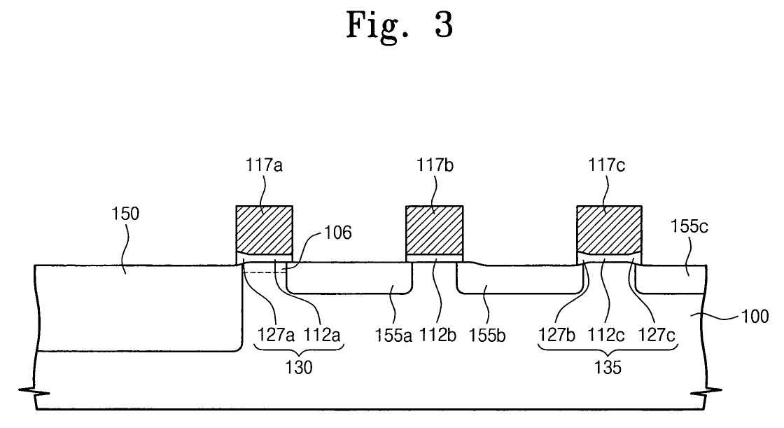

Example Embodiment in FIG. 3

FIG. 3 is a profile view of an example embodiment CMOS image sensor.

As shown in FIG. 3, a device isolation layer (not shown) defining an active region may be in a region of a semiconductor substrate 100. A transfer gate 117a, a reset gate 117b, and/or a sensing gate 117c may be on the active region. The transfer gate 117a, the reset gate 117b, and the sensing gate 117b may be spaced apart from each other side by side. The transfer gate 117a, the reset gate 117b, and/or the sensing gate 117b may overlap the active region. A photodiode region 150 may be on the active region at one side of the transfer gate 117a. A floating doped region 155a may be on the other side of the transfer gate 117a. The floating doped region 155a may be on the active region between the transfer gate 117a and the reset gate 117b. A first doped region 155b and/or a second doped region 155c may be on the active region at either side of the sensing gate 117c. The first doped region 155b may be on the active region between the reset gate 117b and the sensing gate 117c. The bottom of the photodiode region 150 may be deeper than the bottoms of the floating doped region 155a, the first doped region 155b, and/or the second doped region 155c.

The transfer gate 117a may correspond to the gate of the transfer transistor Tt of FIG. 2. The reset gate 117b may correspond to the gate of the reset transistor Tr of FIG. 2. The sensing gate 117c may correspond to the gate of the sensing transistor Ts of FIG. 2. A supply voltage may be applied to the first doped region 155b. The second doped region 155c may be connected to the drain of the access transistor Ta of FIG. 2. Although not illustrated, the gate of the access transistor Ta may be on the active region.

A transfer gate insulating pattern 130 may be between the transfer gate 117a and the active region. The transfer gate insulating pattern 130 may include a first part 127a and/or a second part 112a side by side. The first part 127a may be adjacent to the photodiode region 150 and the second part 112a may be adjacent to the floating doped region 155a. The first part 127a may be thicker than the second part 112a such that an edge of the transfer gate insulating pattern 130 adjacent to the photodiode region 150 may be thicker than the other edge of the transfer gate insulating pattern 130 adjacent to the floating doped region 155a. As illustrated, the thickness of the first part 127a may increase with proximity to the photodiode region 150. The second part 112a may have a substantially uniform thickness. The first and second parts 127a and 112a may contact each other. The edge of the first part 127a may overlap the photodiode region 150. That is, the photodiode region 150 and one edge of the transfer gate 117a may overlap with each other. The edge of the second part 112a may overlap the floating doped region 155a. That is, the floating doped region 155a may overlap with the other edge of the transfer gate 117a.

A transfer channel region may be defined on the active region below the transfer gate 117a. A channel doped region 106 may be on the transfer channel region. The channel doped region 106 may be doped with dopant identical to that of the substrate 100 and different from those of the photodiode region 150 and the floating doped region 155a. The channel doped region 106 may have a dopant concentration that decreases with proximity to the floating doped region 155a. An energy band of the transfer channel region may decrease with proximity to the floating doped region 155a. Consequently, during image sensor operation, electric charge, which may accumulate in the photodiode region 150 due to incident light, may accelerate through the decreasing energy band of the of the transfer channel region, such that the electric charge may move into the floating doped region 155a. Accumulated electric charge may thus promptly transfer into the floating doped region 155a.

A reset gate insulating pattern 112b may be between the reset gate 117b and the active region. A first edge of the reset gate insulating pattern 112b adjacent the floating doped region 155a may have a thickness substantially equal to that of the second part 112a. That is, the first edge of the reset gate insulating pattern 112b may be thinner than the first part 127a. The first edge of the reset gate insulating pattern 112b may overlap the floating doped region 155a. The reset gate insulating pattern 112b may have a substantially uniform thickness. Alternatively, although not illustrated, a second edge of the reset gate insulating pattern 112b adjacent to the first doped region 155b may be thicker than the first edge of the reset gate insulating pattern 112b. In this case, a hot carrier phenomenon around the second edge of the reset gate insulating pattern 112b may be reduced or minimized by a supply voltage applied to the first doped region 155b during a reset operation.

A sensing gate insulating pattern 135 may be between the sensing gate 117c and the active region. The sensing gate insulating pattern 135 includes a first part 127b, a second part 112c, and a third part 127c, which may be side by side. The first part 127b may be adjacent to the first doped region 155b, and the third part 127c may be adjacent to the second doped region 155c. The first part 127b may be thicker than the second part 112c. The first part 127b may have a thickness that increases with proximity to the first doped region 155b. The first part 127b may be shaped substantially similar to that of the first part 127a. The second part 112c may have a substantially uniform thickness that may be identical to that of the second part 112a. The third part 127c may be symmetric to the first part 127b about the center of the sensing gate insulating pattern 135. The third part 127c may be omitted such that the sensing gate insulating pattern 135 may include only the first and second parts 127b and 112c. In this case, the second part 112c may extend to the second doped region 155c.

The photodiode region 150, the first doped region 155b, and/or the second doped region 155c may have top surfaces below that of the floating doped region 155a.

The first part 127a of the transfer gate insulating pattern 130 adjacent to the photodiode region 150 may be thicker than the second part 112a of the transfer gate insulating pattern 130 adjacent to the floating doped region 155a. If a voltage is applied to the transfer gate 117a, an electric field affecting an edge of the photodiode 150 adjacent to the transfer gate 117a may be reduced due to a disparity in edge thickness. This electric field reduction may reduce dark current by minimizing or reducing trapped electric charge, such that CMOS image sensor characteristic deterioration may be reduced or minimized.

The second part 112a may be thinner than the first part 127a. A first overlap capacitance in a first overlap region between the transfer gate 117a and the floating doped region 155a may not be reduced. The floating capacitor Cf of FIG. 2 may be in the floating doped region 155a. The floating capacitor Cf may store electric charge in the photodiode region 150. The first overlap capacitor may be a part of the floating capacitor Cf. Because the second part 112a may be thinner than the first part 127a, the capacity of the first overlap capacitor and thus the floating capacitor Cf may not be reduced.

If the first overlap capacitance is reduced, the size of the floating doped region 1555a may need to be increased to satisfy the required floating capacitance of the CMOS image sensor.

A second overlap capacitance in the second overlap region between the reset gate 117b and the floating doped region 155a may be a part of the floating capacitor Cf. A first edge of the reset gate insulating pattern 112b in the second overlap region may be thin like the second part 112a. Capacitance of the second overlap capacitor may not be reduced. Thus, size of the floating doped region 155a may be reduced through sufficient overlap capacitance of the floating capacitor Cf.

The first part 127b adjacent to the first doped region 155b to which a supply voltage may be applied may be thicker than the second part 112c. An electric field generated by the sensing gate 117c may be reduced at an edge of the first doped region 155b adjacent to the sensing gate 117c. Consequently, a hot carrier phenomenon that may occur in a channel region below the sensing gate 117c adjacent to the first doped region 155b may be reduced or minimized.

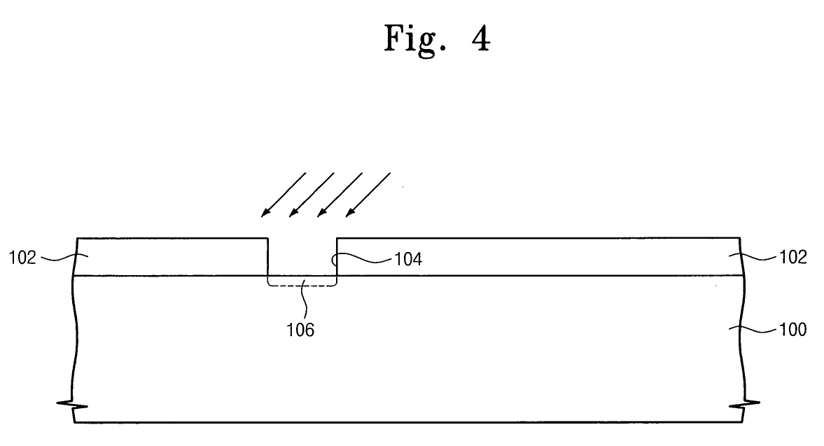

FIGS. 4 through 7 are profile views illustrating an example method of forming a CMOS image sensor.

As shown in FIG. 4, a device isolation layer (not shown) may be formed on a region of the substrate 100 to define an active region. The active region may be doped with dopants. A mask layer 102 may be formed on the substrate, and the mask layer 102 may be patterned to form an opening 104. The opening 104 may pass through the mask layer 102 and may be aligned with a region of the active region. Before forming the mask layer 102, an ion injection buffer oxide layer (not shown) may be formed on the active region. The opening 104 may expose the ion injection buffer oxide layer in the region of the active region. The mask layer 102 may be, for example, a photoresist layer.

The first dopant ions may be implanted at an angle to form a channel doped region 106 by using a mask layer having the opening 104 as an ion injection mask. Due to the angled injection, the dopant concentration of the channel doped region 106 may be non-uniform. The dopant concentration of the channel doped region 106 may decrease from one side of the opening 104 to the other. The first dopant ions may substantially similar to the dopants doped into the active region. The first dopant ions may be implanted at an angle favoring a relatively higher concentration region of the channel doped region 106. Alternatively, the first dopant ions may be different from the dopants doped in the active region. In this case, the first dopant ions may be implanted at an angle favoring a relatively lower concentration region of the channel doped region 106. In this case, the first dopant ions reduce the doping concentration of the active region.

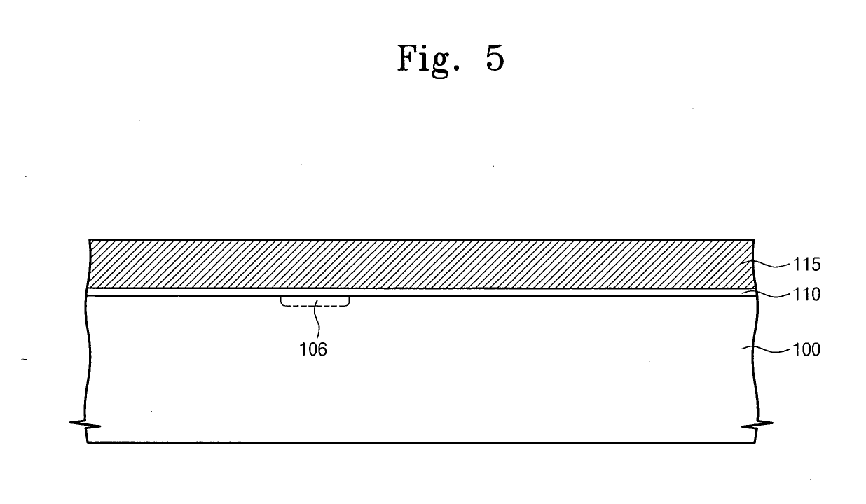

As shown in FIG. 5, the mask layer 102 may be removed and the top of the active region may be exposed. An insulating layer 110 and a gate conductive layer 115 may be layered on the substrate 100 having the exposed active region. The insulating layer 110 may be formed of an oxide, a thermal oxide, and/or another suitable insulator. The gate conductive layer 115 may be formed of a conductive material. A lower portion of the gate conductive layer 115 may be formed of doped polysilicon. An upper portion of the gate conductive layer 115 may be formed of metal and/or another conductive material including metal.

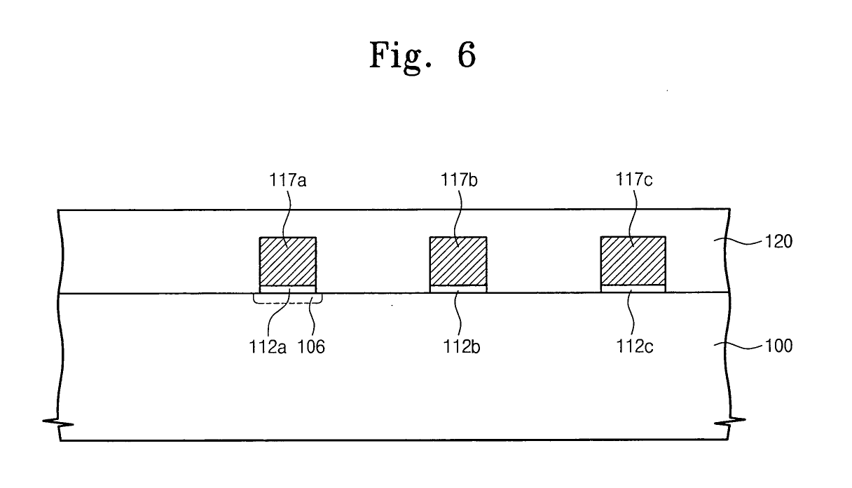

As shown in FIG. 6, the gate conductive layer 115 and insulating layer 110 may be patterned to form a first insulating pattern 112a and a transfer gate 117a stacked on the active region and/or channel region 106. Likewise, a second insulating pattern 112b and a reset gate 117b may be formed on the active region, and a third insulating pattern 112c and a sensing gate 117c may be formed on the active region. The first, second, and third insulating patterns 112a, 112b, and 112c may be formed from part of the insulating layer 110. The insulating layer 110 on either side of the respective gates 117a, 117b, and 117c may be removed using a wet etching process.

An oxidation-blocking layer 120 may be formed on and/or over the substrate 100. The oxidation-blocking layer 120 may be formed of an oxide, a nitride, and/or another suitable oxidation-blocking material.

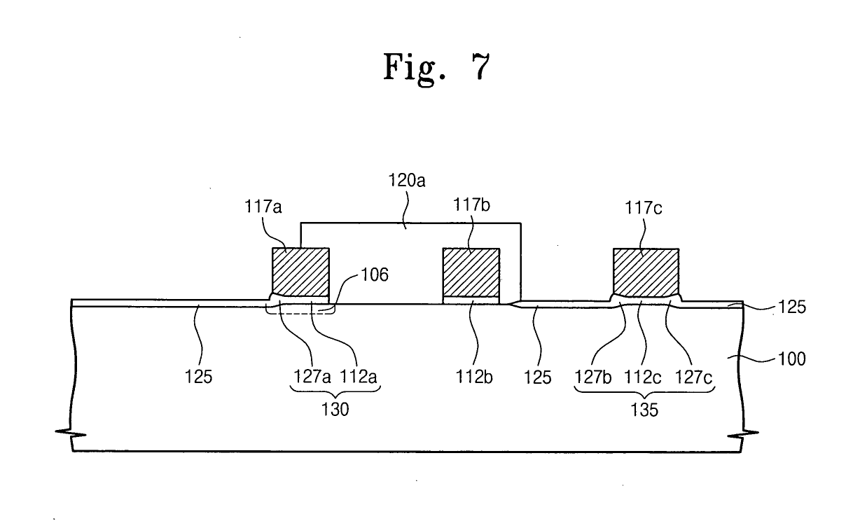

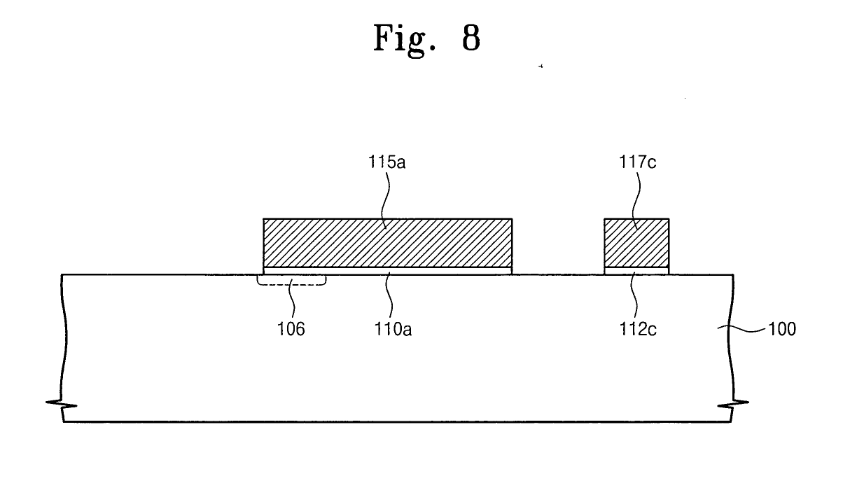

As shown in FIG. 7, the oxidation-blocking layer 120 may be patterned to form an oxidation-blocking pattern 120a. The oxidation-blocking pattern 120a may cover the active region between the transfer and reset gates 117a and 117b, the sides of the transfer gate 117a and the first insulating pattern 112a, and the sides of the reset gate 117b and the second insulating pattern 112b, which may be adjacent to the active region between the transfer and reset gates 117a and 117b. Sides of the transfer gate 117a and/or the first insulating pattern 112a adjacent to a region where the next photodiode region may be formed may be exposed. Sides of the sensing gate 117c and/or the third insulating pattern 112c may also be exposed.

The oxidation-blocking pattern 120a may cover the reset gate 117b and the second insulating pattern 112b. Alternatively, the oxidation-blocking pattern 120a may not cover a side of the second insulating pattern 112b and the reset gate 117b closest to the sensing gate 117c.

A thermal oxidation process may be performed on the substrate 100. By the thermal oxidation process, a lower edge of the transfer gate 117a adjacent to the exposed side of the first insulating pattern 112a may be oxidized. The active region adjacent to the exposed side of the first insulating pattern 112a may be oxidized. Likewise, the thermal oxidation process may thicken exposed edges of the third insulating pattern 112c such that the first part 127b and the third part 127c may be formed. The first insulating pattern 112a remaining to the side of the first part 127a may correspond to the second part 112a of FIG. 3, and the second insulating pattern 112c between the first part 127b and the third part 127c may correspond to the second part 112c of FIG. 3. The first and second parts 127a and 112a may constitute the transfer gate insulating pattern 130, and the first, second, and third parts 127b, 112c, and 127c may constitute the sensing gate insulating pattern 135. The second insulating pattern 112b may correspond to the reset gate insulating pattern.

A thermal oxide layer 125 may be formed on the exposed active region by a thermal oxidation process or another suitable process. Although not illustrated, a thermal oxide layer may be formed on the exposed surfaces of the transfer gate 117a and the sensing gate 117c.

The oxidation-blocking pattern 120a may be selectively removed and the thermal oxide layer 125 may be selectively removed. The thermal oxide layer 125 may be removed by using, for example, a wet etching process. The top of the active region where the thermal oxide layer 125 is removed may be lower than the top of the active region that the oxidation-blocking pattern covered.

Second dopant ions may be selectively implanted on the photodiode region. Third dopant ions may be selectively implanted to form the floating doped region 155a, the first doped region 155b, and the second doped region 155c. After forming the photodiode region 150, the doping regions 155a, 155b, and/or 155c may be formed. Alternatively, after forming the doping regions 155a, 155b, and/or 155c, the photodiode region 150 may be formed.

Forming the oxidation-blocking pattern 120a may include forming a second oxidation-blocking pattern (not shown). The second oxidation-blocking pattern may cover a portion of the sensing gate insulation pattern 135 and the sensing gate 117c. A side of the sensing gate insulation pattern 135 and the sensing gate 117c closest to the reset gate 117b may be exposed, and other sides of the sensing gate insulating pattern 135 and the sensing gate 117c relatively farther from the reset gate 117b may be covered by the second oxidation-blocking pattern. The third part 127c of FIG. 3 may not be formed if the second oxidation-blocking pattern is formed.

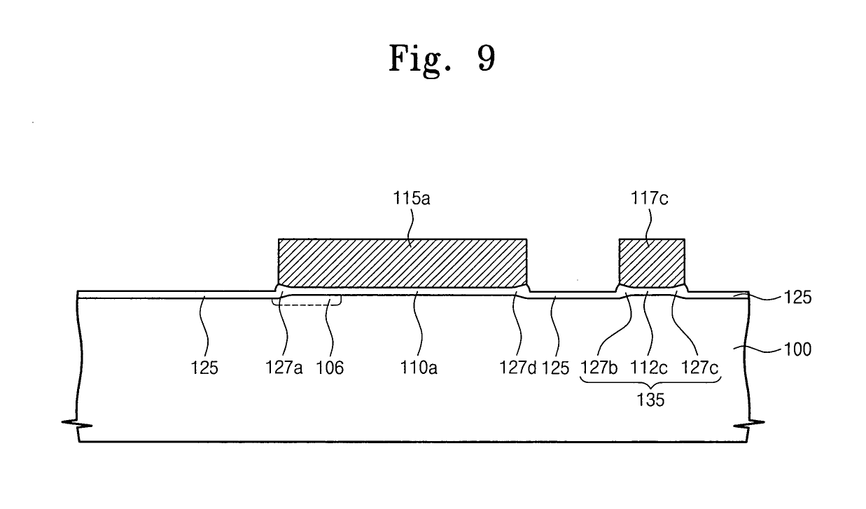

FIGS. 8 through 10 are profile views illustrating an example method of forming a CMOS image sensor.

As shown in FIG. 8, a first patterning process may be performed on the gate conductive layer 115 and the insulating layer 110 (shown in FIG. 5). The first patterned insulating layer 110a and the first patterned gate conductive layer 115 may be stacked. The third insulating pattern 112c and the sensing gate 117c may be stacked.

As shown in FIG. 9, a thermal oxidation process may be performed on the substrate 100. A first edge of the first patterned insulating layer 110a may be thicker and form the first part 127a of FIG. 3. Both sides of the third insulating pattern may be thicker to form the first part 127b and the third part 127c of FIG. 3. A second edge of the first patterned insulating layer 110a may be thicker and form the edge 127d. A thermal oxide layer 125 may be formed on the surface of the active region. A thermal oxide layer (not shown) may be formed on surfaces of the first patterned gate conductive layer 115a and sensing gate 117a.

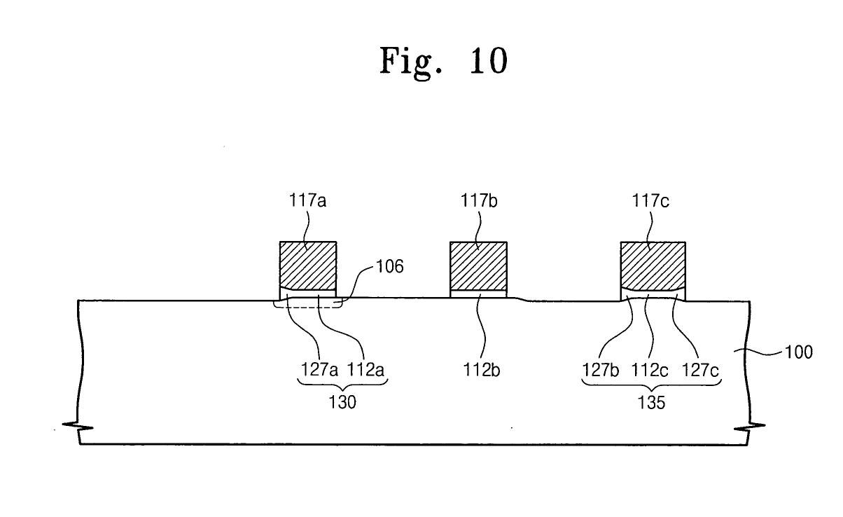

As shown in FIG. 10, a second patterning process may be on the first patterned gate conductive layer 115a and the first patterned insulating layer 110a to form transfer gate insulating pattern 112a and transfer gate 117a and/or gate insulating pattern 112b and reset gate 117b. In example methods, the oxidation-blocking layer 120 of FIGS. 6 and 7 may not be required.

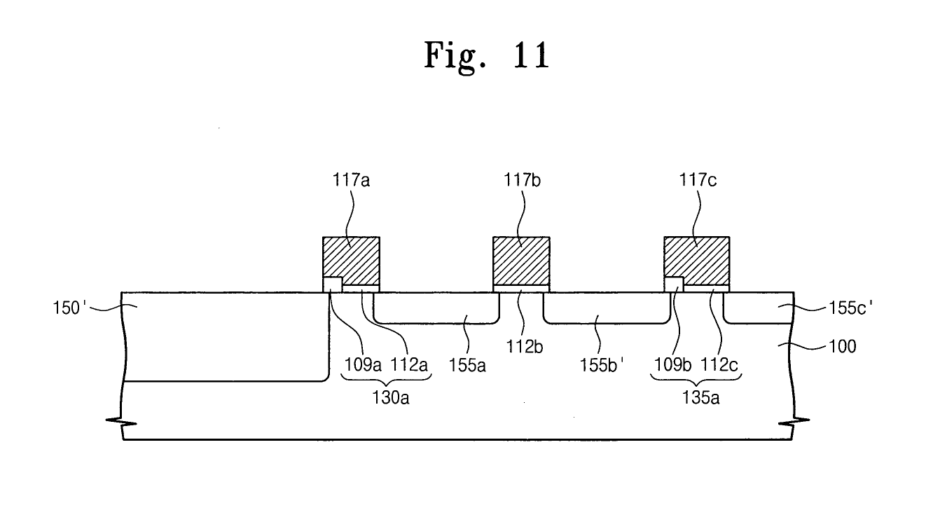

Example Embodiment in FIG. 11

FIG. 11 is a profile view of an example embodiment CMOS image sensor. A relatively thicker first part of a transfer gate insulating pattern may have alternate forms. A relatively thicker first part in a sensing gate insulating pattern may have alternate forms. In the detailed description of the example embodiment in FIG. 11, elements redundant with those in FIG. 3 may be omitted.

As shown in FIG. 11, a transfer gate insulating pattern 130a between a transfer gate 117a and an active region may include a first part 109a and an adjacent second part 112a. The first part 109a may be adjacent to a photodiode region 150′, and the second part 112a may be adjacent to a floating doped region 155a. The first part 109a may be thicker than the second part 112a. The first part 109 may have a substantially uniform thickness.

A sensing gate insulating pattern 135a between the sensing gate 117c and the active region may include a third part 109b and/or a fourth part 112c side by side. A first doped region 155b′ and a second doped region 155c′ may each be on the active region of either side of the sensing gate 117c. The first doped region 155b may be on the active region between the reset gate 117b and the sensing gate 117c. A supply voltage may be applied to the first doped region 155b′. The third part 109b may be adjacent to the first doped region 155b′ and the fourth part 112c may be adjacent to the second doped region 155c′. The third part 109b may be thicker than the fourth part 112c. The third part 109b may have a uniform thickness. The third part 109b may be substantially similar to the first part 109b. That is, the first and third parts 109a and 109b may have the substantially similar thickness.

A channel doped region 106 may be on a channel region below the transfer gate 117a. The top surfaces of the photodiode region 150′, the first doped region 155b′, and/or the second doped region 155c′ may have substantially similar height as the top surface of the floating doped region 155a.

The first part 109a may be thicker than the second part 112a, and the third part 109b may be thicker than the fourth part 112c. This thickness disparity may have the same effectiveness as described in other example embodiments.

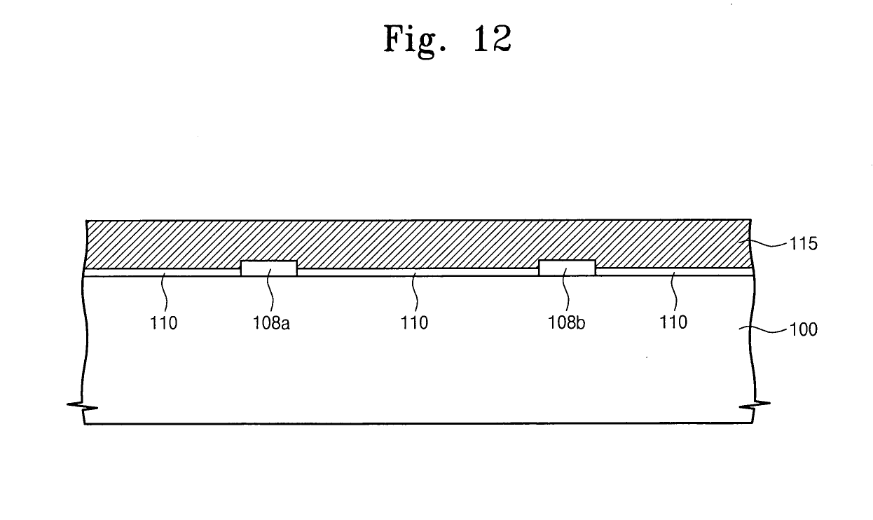

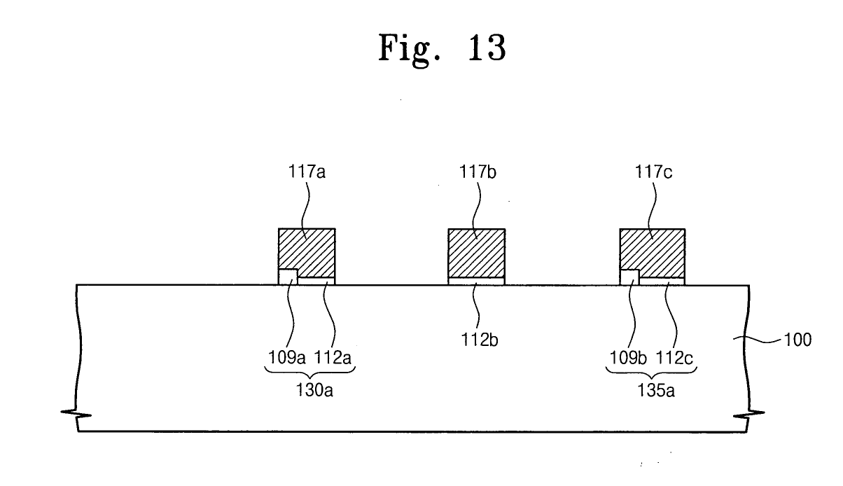

FIGS. 12 and 13 are profile views illustrating an example method of forming a CMOS image sensor.

As shown in FIG. 12, a thicker insulating layer (not shown) may be formed on a substrate 100 having an active region. is the insulating layer may be patterned to form a first thicker insulating pattern 108a and/or second thicker insulating pattern 108b that are spaced apart from each other. The first and second thicker insulating patterns 108a and 108b may include an oxide, a thermal oxide, and/or another suitable insulator material. An insulating layer 110 may be formed on the active region next to the thicker insulating patterns 108a and 108b. The insulating layer 100 may be thinner than the thicker insulating patterns 108a and 108b. The insulating layer 110 may be formed of an oxide layer, for example, a thermal oxide layer. A gate conductive layer 115 may be formed on a surface of the substrate 100.

Before the forming of the thicker insulating layer, the channel doped region 106 may be formed using an angled injection of first dopant ions as illustrated in FIG. 4.

As shown in FIG. 13, the gate conductive layer 115, the thicker insulating patterns 108a and 108b, and the insulating layer 110 may be patterned to form layered transfer gate insulating pattern 130a and the transfer gate 117a, reset gate insulating pattern 112b and the reset gate 117b, and/or sensing gate insulating pattern 135a and the sensing gate 117c.

The first part 109a of the transfer gate insulating pattern 130a may be formed from a portion of the first thicker insulating pattern 108a, and the second part 112a may be formed from a portion of the insulating layer 110. The reset gate insulating pattern 112b may be formed as a portion of the insulating layer 110. The third part 109b of the sensing gate insulating pattern 135a may be formed from a portion of the second thicker insulating pattern 108b, and the fourth part 112c may be formed from a portion of the insulating layer 110.

The second dopant ions may be selectively implanted to form the photodiode region 150′ of FIG. 11. The second dopant ions may be selectively implanted to form doping regions 155a, 155b′, and/or 155c′ of FIG. 11. After forming the photodiode region 150′, the doping regions 155a, 155b′, and/or 155c′ may be formed. Alternatively, after forming the doping regions 155a, 155b′, and 155c′, the photodiode region 150′ may be formed. A thermal oxidation process may not be required.

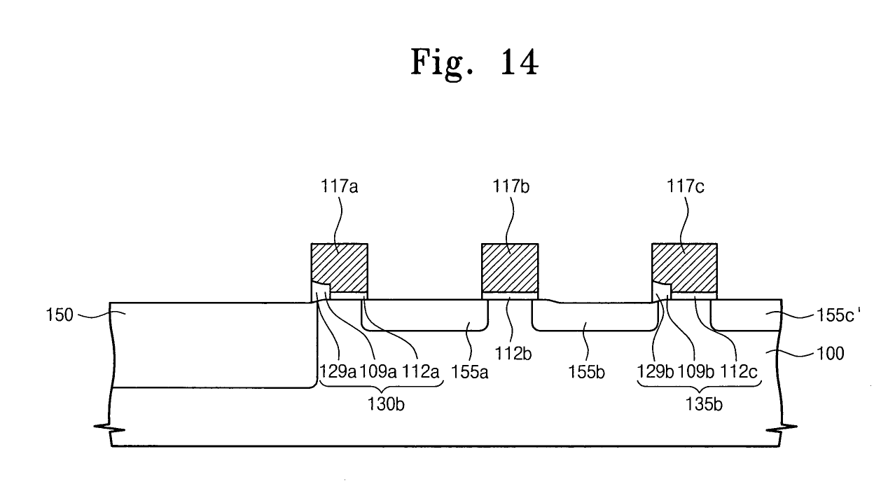

Example Embodiment in FIG. 14

FIG. 14 is a profile view of an example embodiment CMOS image sensor. A relatively thicker first part in a transfer gate insulating pattern may have an alternate form. A relatively thicker third part in a sensing gate insulating pattern may have another form. In the detailed description of the example embodiment in FIG. 14, elements redundant with those in FIG. 3 and/or 11 may be omitted.

As shown in FIG. 14, the transfer gate insulating pattern 130b between the transfer gate 117a and the active region may include a first part 129a/109a and a second part 112a that may be adjacent. The first part 129a/109a may be adjacent to the photodiode region 150, and the second part 112a may be adjacent to the floating doped region 155a. The first part 129a/109a may be thicker than the second part 112a. The first part 129a/109a may include a first uniform region 109a and/or a first non-uniform region 129a. The first uniform region 109a may be adjacent to the second part 112a, and the first non-uniform region 129a may be adjacent to the photodiode region 150. The first uniform region 109a may have a substantially uniform thickness. The first non-uniform region 129a may have a thickness that increases with proximity to the photodiode region. The first non-uniform region 129a may be thicker than to the first uniform region 109a. The channel doped region 106 of FIG. 3 may be on the channel region below the transfer gate insulating pattern 130b.

The sensing gate insulating pattern 135b may be between the sensing gate 117c and the active region. The sensing gate insulating pattern 135b may include a third part 129b/109b and an adjacent fourth part 112c. The third part 129b/109b may be thicker than the fourth part 112c. The third part 129b/109b may include a second uniform region 109b and an adjacent second non-uniform region 129b. The second uniform region 109b may be adjacent to the fourth part 112c, and the second non-uniform region 129b may be adjacent to the first doped region 155b. The second uniform region 109b may have a substantially uniform thickness, and the second non-uniform region 129b may have a thickness that increases with proximity to the first doped region 155b from the second uniform region 109b. The second non-uniform region 129b may be thicker than the second uniform region 109b.

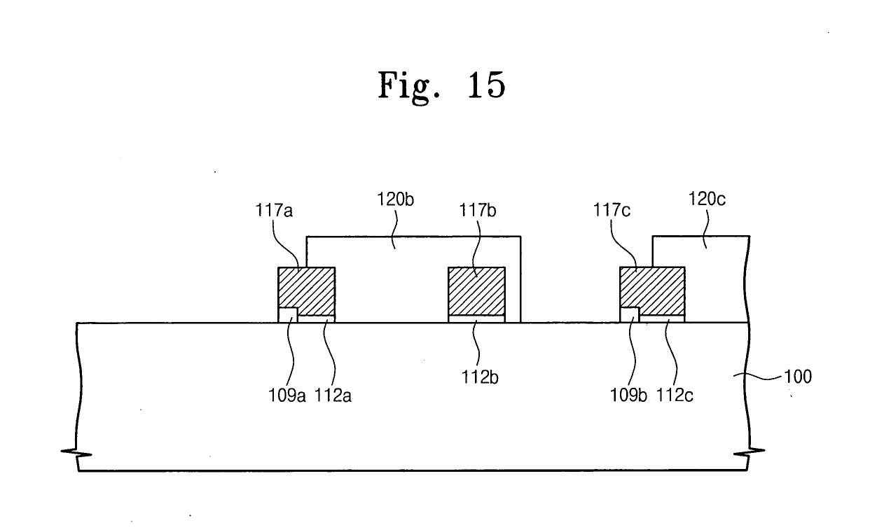

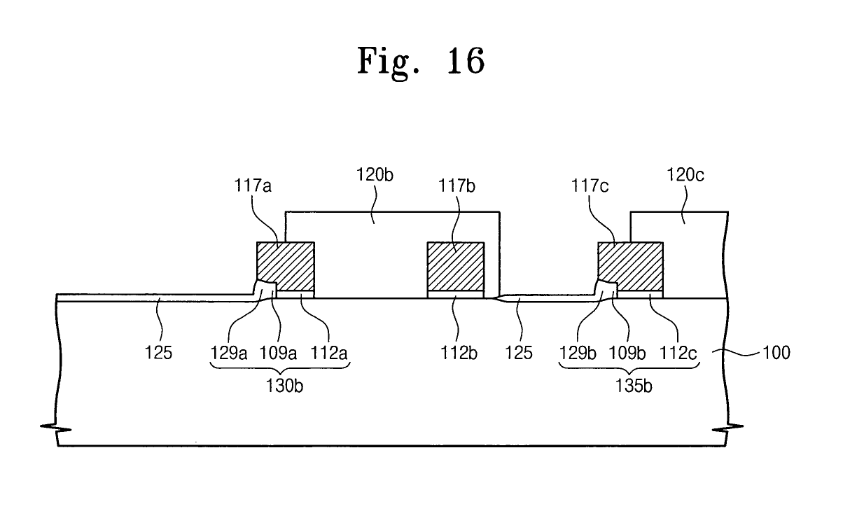

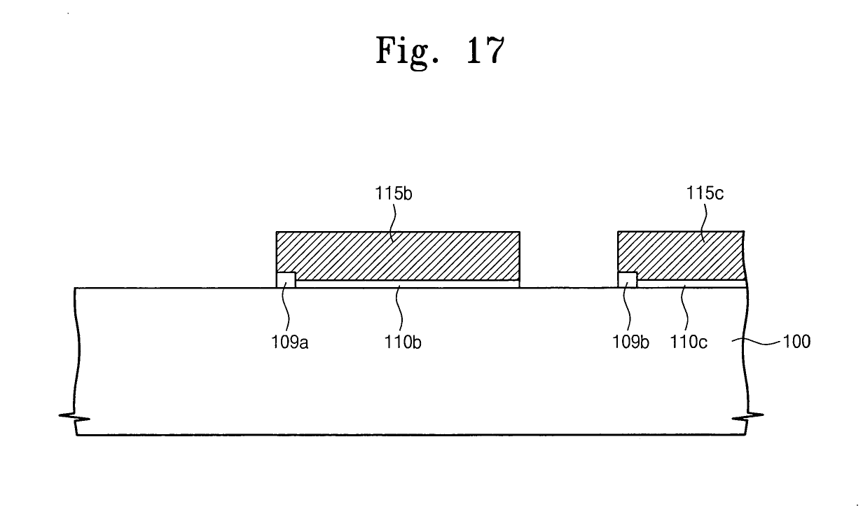

FIGS. 15 and 16 are profile views illustrating an example method of forming an image sensor. As shown in FIG. 15, an oxidation-blocking layer (not shown) may be formed on a surface of the substrate 100 having gates 117a, 117b, and/or 117c, and may be patterned to from first and second oxidation-blocking patterns 120b and 112c. The first part 109a and the second part 112a may be adjacent between the transfer gate 117a and the active region, and the third part 109b and the fourth part 112c may be adjacent between the sensing gate 117c and the active region. The first oxidation-blocking pattern 120b may cover the active region where the floating doped region may be formed. The first oxidation-blocking pattern 120b may cover a side of the transfer gate 117a, the second part 112a, the reset gate insulating pattern 112b, and/or the reset gate 117b adjacent to the active region. A first oxidation-blocking pattern 120b may cover the entire reset gate 117b and the reset gate insulating pattern 112b. A side of the first part may be exposed. The second oxidation-blocking pattern 120b may cover a side of the sensing gate 117c and a side of the fourth part 112c. A side of the third part 109b closest to the reset gate 117b may be exposed.

As shown in FIG. 16, a thermal oxidation process may be performed on the substrate 100 having the oxidation-blocking patterns 120b and 120c. The transfer gate insulating pattern 130b of FIG. 14 may be formed between the transfer gate 117a and the active region, and the reset gate insulating pattern 135b may be formed between the sensing gate 117c and the active region.

The oxidation-blocking patterns 120b and 120c may be removed, and the thermal oxide layer 125 on the active region may be removed. The photodiode region 150 and the doping regions 155a, 155b, and 155c′ are formed in accordance with previous example embodiments.

FIGS. 17 through 19 are profile views illustrating an example method of forming an image sensor.

As shown in FIGS. 12 through 17, a first patterning process may be performed on the gate conductive layer 117, the first and second thicker insulating patterns 108a and 108b, and/or the insulating layer 110. A first preliminary gate pattern 115b and/or a second preliminary gate pattern 115c may be formed on the substrate 100. The first and second preliminary gate patterns may be spaced apart. The first thicker insulating pattern 109a and the first thinner insulating pattern 110b may be side by side between the first preliminary gate pattern 115b and the active region, and the second thicker insulating pattern 109b and the second thinner insulating pattern 110c may be adjacent between the second preliminary gate pattern 115b and the active region.

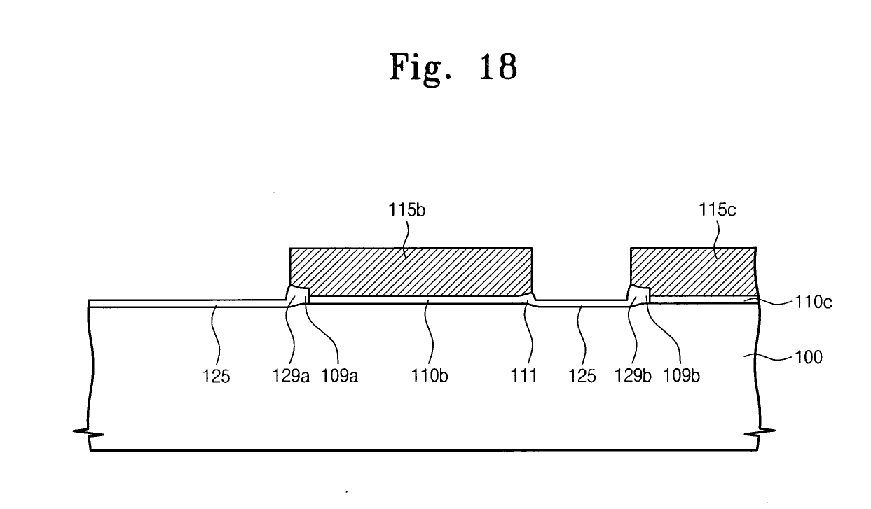

As shown in FIG. 18, a thermal oxidation process may be performed on the substrate 100. An edge of the first thicker insulating pattern 109a having the exposed side may form the first non-uniform region 129a of FIG. 14. An edge of the second thicker insulating pattern 109b having the exposed side may form the second non-uniform region 129b. The remaining first thicker insulating pattern 109a may correspond to the first uniform region 109a, and the remaining second thicker insulating pattern 109b may correspond to the second uniform region 109b. During a thermal oxidation process, the edge 111 of the first thinner insulating pattern 110b may be formed thicker than the first thinner insulating pattern 110b.

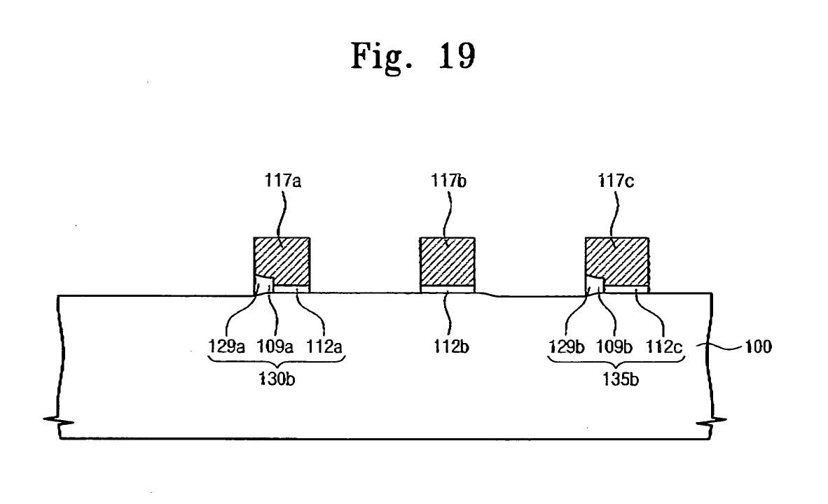

As shown in FIG. 19, the first preliminary gate pattern 115b may be patterned to form the transfer gate 117a and the reset gate 117b, and the second preliminary gate pattern 115c may be patterned to form the sensing gate 117c. The insulation materials next to the gates 117a, 117b, and 117c may be removed by using a wet etching process. The transfer gate insulating pattern 130b may be formed between the transfer gate 117a and the active region, and the reset gate insulating pattern 112b may be formed between the reset gate 117b and the active region. The sensing gate insulating pattern 135c may be formed between the sensing gate insulating pattern 117c and the active region.

The photodiode region and the doping region may be formed by example methods previously described.

Example embodiments may have a first part adjacent to a photodiode region of a transfer gate insulating pattern thicker than a second part adjacent to a floating doped region. Therefore, electric field in an adjacent portion between the photodiode region and the transfer gate may be reduced and dark current may be decreased, thereby reducing or minimizing the deterioration of the CMOS image sensor quality.

While example embodiments have been particularly shown and described, it will be understood by those of ordinary skill in the art that various changes in form and details may be made therein without departing from the spirit and scope of the present invention as defined by the following claims.

What is claimed is:

1. A Complementary Metal-Oxide-Silicon (CMOS) image sensor comprising:
a substrate having an active region;
a transfer gate on the active region;
a photodiode region on the active region on a first side of the transfer gate;
a floating doped region on the active region on a second side of the transfer gate; and
a transfer gate insulating pattern between the transfer gate and the active region, the transfer gate insulating pattern including,
a first part adjacent to the photodiode region, and
a second part adjacent to the floating doped region, the second part being thinner than the first part.

2. The CMOS image sensor of claim 1, wherein a thickness of the first part increases with proximity to the photodiode region.

3. The CMOS image sensor of claim 1, wherein the first part has a substantially uniform thickness.

4. The CMOS image sensor of claim 1, wherein the first part includes,
a uniform region adjacent to the second part, the uniform region having a substantially uniform thickness, and
a non-uniform region adjacent to the photodiode region, the non-uniform region having a thickness that increases with proximity to the photodiode region.

5. The CMOS image sensor of claim 1, wherein the second part has a substantially uniform thickness and includes an edge adjacent to the floating doped region, the edge overlapping with an edge of the floating doped region.

6. The CMOS image sensor of claim 1, further comprising:
a channel doped region in the active region below the transfer gate, the channel doped region having a dopant concentration that decreases with proximity to the floating doped region.

7. The CMOS image sensor of claim 1, further comprising:
a sensing gate disposed on the active region and electrically connected to the floating doped region;
a first doped region on the active region at a first side of the sensing gate;
a second doped region on the active region at a second side of the sensing gate; and
a sensing gate insulating pattern between the sensing gate and the active region, the sensing gate insulating pattern including,
a third part adjacent to the first doped region, and
a fourth part adjacent to the third part, the fourth part being thinner than the third part.

8. The CMOS image sensor of claim 7, wherein the third part is substantially similar to the first part.

9. The CMOS image sensor of claims 7, wherein the fourth part has a substantially uniform thickness.

10. The CMOS image sensor of claims 7, wherein the sensing gate insulating pattern further includes a fifth part adjacent to the fourth part and adjacent to the second doped region, the fourth part being between the third part and the fifth part, the fifth part being substantially symmetrical to the third part about a center of the sensing gate insulating pattern.

11. The CMOS image sensor of claim 7, further comprising:
a reset gate on the active region between the floating doped region and the first doped region; and
a reset gate insulating pattern between the reset gate and the active region.

12. The CMOS image sensor of claim 7, wherein the first doped region includes a first dopant, and wherein the second doped region includes a second dopant.

13. A method of forming a Complementary Metal-Oxide-Silicon (CMOS) image sensor, the method comprising:
forming a transfer gate insulating pattern on an active region of a substrate, the transfer gate insulating pattern including,
a first part, and
a second part adjacent to the first part, the second part being thinner than the first part;
forming a transfer gate on the transfer gate insulating pattern;
forming a photodiode region in the active region at a first side of the transfer gate, the first side including the first part; and
forming a floating doped region in the active region at a second side of the transfer gate, the second side including the second part.

14. The method of claim 13, wherein the first part includes a thickness that increases with proximity to the photodiode region.

15. The method of claim 14, further comprising:
forming an oxidation-blocking pattern covering the second side of the transfer gate and exposing the first side of the transfer gate; and
performing a thermal oxidation process on the substrate.

16. The method of claim 14, wherein forming the transfer gate insulating pattern and forming the transfer gate includes,
forming an insulating layer on the active region;
forming a gate conductive layer on the insulating layer;
patterning the gate conductive layer and the insulating layer to form the transfer gate and the transfer gate insulating pattern;
performing a thermal oxidation process on the first side of the transfer gate and the transfer gate insulating pattern; and
patterning the first side of the transfer gate and the transfer gate insulating pattern.

17. The method of claim 13, wherein forming the transfer gate insulating pattern and the transfer gate includes
forming a first insulating pattern on the active region;
forming an insulating layer on the active region next to the first insulating pattern, the insulating layer being thinner than the first insulating pattern;
forming a gate conductive layer on the substrate; and
patterning the gate conductive layer, the first insulating pattern, and the insulating layer so as to form the first part from a part of the first insulating pattern and the second part from a part of the insulating layer.

18. The method of claim 17, further comprising:
performing a thermal oxidation process on the first side, wherein,
the first part includes a uniform region and a non-uniform region, the non-uniform region formed by the thermal oxidation process, and
wherein the non-uniform region has a thickness that increases with proximity to the photodiode region.

19. The method of claim 13, further comprising;
forming a mask layer on entire surface of the substrate before forming the transfer gate;
forming an opening that passes through the mask layer; and
injecting dopant ions into the substrate at an angle by using the mask layer having the opening as an ion injection mask, so as to form a channel doped region at the active region, wherein the transfer gate is formed on the channel doped region, and wherein the channel doped region has a dopant concentration that decreases with proximity to the floating doped region.

20. The method of claim 13, further comprising:
forming a sensing gate insulation pattern on the active region, the sensing gate insulation pattern including,
a third part, and
a fourth part adjacent to the third part and thinner than the third part;
forming a sensing gate on the sensing gate insulation pattern, the sensing gate being electrically connected to the floating doped region;
forming a first doped region in the active region adjacent to the third part; and
forming a second doped region in the active region at a side of the sensing gate insulation pattern closest to the fourth part.

21. The method of claim 20, wherein the third part is formed substantially similarly as the first part.

22. The method of claim 20, wherein the sensing gate insulation pattern further includes a fifth part next to the fourth part and adjacent to the second doped region, the fourth part being between the third part and the fifth part, the fifth part being substantially symmetrical to the third part about a center of the sensing gate insulation pattern.

23. The method of claim 20, further comprising:
forming a reset gate insulation pattern on the active region between the floating doped region and the first doped region; and
forming a reset gate on the reset gate insulation pattern.
